(19) United States
(12) Patent Application Publication
(10) Pub. No.: US 2016/0362785 A1
(43) Pub. Date: Dec. 15, 2016

(54) APPARATUS FOR MANUFACTURING SEMICONDUCTOR DEVICE HAVING A GAS MIXER

(71) Applicant: Samsung Electronics Co., Ltd., Suwon-si (KR)

(72) Inventors: Dongyoung KIM, Pohang-si (KR); Yongsoon CHOI, Seoul (KR); Honggun KIM, Hwaseong-si (KR); Jongmyeong LEE, Seongnam-si (KR); Byoungdeog CHOI, Suwon-si (KR)

(21) Appl. No.: 15/048,995

(22) Filed: Feb. 19, 2016

(30) Foreign Application Priority Data
Jun. 15, 2015 (KR) 10-2015-0084278

(51) Int. Cl. C23C 16/455; C23C 16/30

(52) U.S. Cl. CPC C23C 16/45512; C23C 16/45565; C23C 16/45561; C23C 16/30; H01J 37/3244

(57) ABSTRACT

An apparatus for manufacturing semiconductor devices having a gas mixer includes a gas supply and a reaction chamber, and the gas supply includes an upper gas mixer, an intermediate gas mixer disposed under the upper gas mixer, a lower gas mixer disposed under the intermediate gas mixer, a first gas supply pipe which is disposed on an upper portion of the upper gas mixer and supplies a first gas to the upper gas mixer, a second gas supply pipe which is disposed on an upper end portion of a side surface of the upper gas mixer and supplies a second gas to the upper gas mixer, and a third gas supply pipe which is disposed on a side surface of the intermediate gas mixer and supplies a third gas to the intermediate gas mixer.

### CROSS-REFERENCE TO RELATED APPLICATION

This application claims priority under 35 U.S.C. §119 to Korean Patent Application No. 10-2015-0084278 filed on Jun. 15, 2015, the disclosure of which is hereby incorporated by reference in its entirety.

### BACKGROUND

1. Field

Embodiments in accordance with the inventive concept relate to an apparatus for manufacturing a semiconductor device having a gas mixer.

2. Description of Related Art

As a design rule of semiconductor devices is gradually decreased and circuit patterns are miniaturized, a process of uniformly forming various material layers on a wafer has emerged as a very important issue. In order to uniformly form the various material layers, uniformly mixed gas should be provided into a reaction chamber.

### SUMMARY

Embodiments in accordance with the inventive concept provide an apparatus for manufacturing semiconductor devices.

Embodiments in accordance with the inventive concept provide an apparatus for manufacturing semiconductor devices having a gas mixer configured to uniformly mix gas mixtures.

Embodiments in accordance with the inventive concept provide an apparatus for manufacturing semiconductor devices having a shower head configured to adjust and distribute gases.

The technical objectives of the inventive concept are not limited to the above disclosure; other objectives may become apparent to those of ordinary skill in the art based on the following descriptions.

In accordance with an aspect of the inventive concept, an apparatus for manufacturing semiconductor devices includes a gas supply and a reaction chamber. The gas supply includes an upper gas mixer, an intermediate gas mixer disposed under the upper gas mixer, a lower gas mixer disposed under the intermediate gas mixer, a first gas supply pipe which is disposed on an upper portion of the upper gas mixer and supplies a first gas to the upper gas mixer, a second gas supply pipe which is disposed on an upper end portion of a side surface of the upper gas mixer and supplies a second gas to the upper gas mixer, and a third gas supply pipe which is disposed on a side surface of the intermediate gas mixer and supplies a third gas to the intermediate gas mixer.

In accordance with another aspect of the inventive concept, an apparatus for manufacturing semiconductor devices includes a gas supply, a shower head, and a reaction chamber. The gas supply includes an upper gas mixer, an intermediate gas mixer connected to a lower portion of the upper gas mixer, a lower gas mixer connected to a lower portion of the intermediate gas mixer and having a cone shape, a first gas supply pipe connected to an upper portion of the upper gas mixer, a second gas supply pipe connected to a side portion of the upper gas mixer, and a third gas supply pipe connected to a side portion of the intermediate gas mixer. The first gas supply pipe, the second gas supply pipe, and the third gas supply pipe each have a circular shape having a smaller diameter than the intermediate gas mixer.

In accordance with still another aspect of the inventive concept, an apparatus for manufacturing semiconductor devices includes a gas supply, a shower head, and a reaction chamber. The gas supply includes an upper gas mixer having an inverted cone shape of which an upper portion is large and a lower portion is small, an intermediate gas mixer connected to the lower portion of the upper gas mixer and having a circular shape, a lower gas mixer connected to a lower portion of the intermediate gas mixer and having a cone shape of which an upper portion is small and a lower portion is large, a first gas supply pipe which supplies a first gas to the upper gas mixer and having a smaller diameter than an average diameter of the upper gas mixer, a second gas supply pipe which supplies a second gas to the upper gas mixer and having a smaller diameter than the average diameter of the upper gas mixer, and a third gas supply pipe which supplies a third gas to the intermediate gas mixer and having a smaller diameter than the average diameter of the upper gas mixer.

Details of other embodiments are included in detailed explanations and the drawings.

### BRIEF DESCRIPTION OF THE DRAWINGS

The foregoing and other features and advantages of the inventive concepts will be apparent from the more particular description of preferred embodiments of the inventive concepts, as illustrated in the accompanying drawings in which like reference characters refer to the same parts throughout the different views. The drawings are not necessarily to scale, emphasis instead being placed upon illustrating the principles of the inventive concepts. In the drawings:

FIG. 1 is a schematic view illustrating an apparatus for manufacturing a semiconductor device in accordance with an embodiment of the inventive concept;

FIGS. 2A and 2B are schematic views illustrating gas supplies according to various embodiments of the inventive concept;

FIGS. 3A to 3C are schematic views illustrating the interior of a lower gas mixer according to embodiments of the inventive concept;

FIGS. 4A and 4B are schematic views illustrating a shower head in accordance with an embodiment of the inventive concept; and

FIGS. 5A and 5B are schematic views illustrating an operation of the shower head.

### DETAILED DESCRIPTION OF THE EMBODIMENTS

Advantages and features of the inventive concept and methods of accomplishing them will be made apparent with reference to the accompanying drawings and some embodiments to be described below. The inventive concept may, however, be embodied in various different forms, and should be construed as limited, not by the embodiments set forth herein, but only by the accompanying claims. Rather, these embodiments are provided so that this disclosure is thorough and complete and fully conveys the inventive concept to those skilled in the art.

The terminology used herein is for the purpose of describing particular embodiments only and is not intended to be limiting of the present inventive concept. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on,” “connected to,” or “coupled to” another element or layer, it can be directly on, connected or coupled to the other element or layer or intervening elements or layers may be present. In contrast, when an element is referred to as being “directly on,” “directly connected to,” or “directly coupled to” another element or layer, there are no intervening elements or layers present. Like reference numerals throughout this specification denote like elements. As used herein, the term “and/or” includes any and all combinations of one or more of the associated listed items.

Spatially relative terms, such as “beneath,” “below,” “lower,” “above,” “upper,” and the like, may be used herein for ease of description in describing one element's or feature's relationship to another/other element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

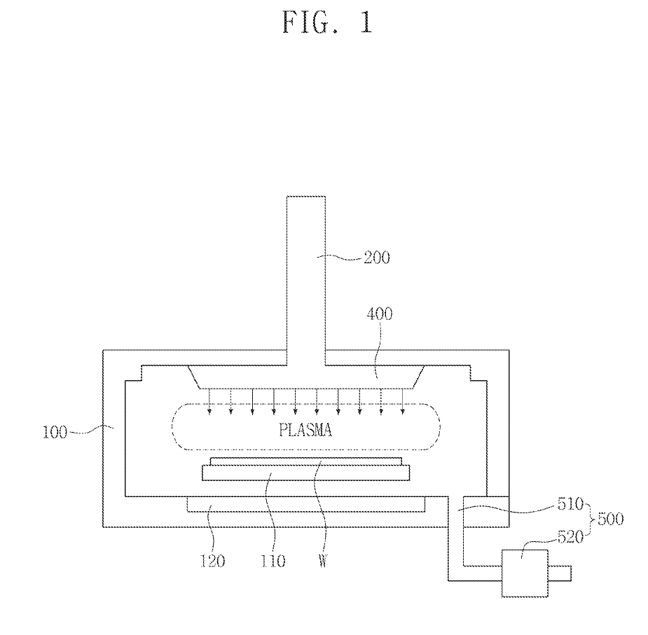

FIG. 1 is a schematic view illustrating an apparatus for manufacturing a semiconductor device in accordance with an embodiment of the inventive concept.

Referring to FIG. 1, the apparatus for manufacturing the semiconductor device in accordance with the embodiment of the inventive concept may include a reaction chamber 100, a gas supply 200 connected to an upper portion of the reaction chamber 100, and a gas exhausting unit 500 connected to a lower portion of the reaction chamber 100.

The reaction chamber 100 may include a susceptor 110 which supports a wafer W, a heater 120 which heats the susceptor 110, and a shower head 400 connected to the gas supply 200. Plasma may be formed in an inside of the reaction chamber 100. The wafer W may be mounted on an upper surface of the susceptor 110. The heater 120 may include a halogen lamp or a heating coil. The heater 120 may be disposed on an outside of the lower portion of the reaction chamber 100. For example, the heater 120 may have a modular form configured to be separated from the reaction chamber 100.

The gas supply 200 may supply source gases, reactive gases, cleaning gases, and purge gases to the inside of the reaction chamber 100. The gas supply 200 will be described in detail below.

The gas exhausting unit 500 may include a gas exhausting pipe 510 connected to the inside of the reaction chamber 100, and a exhausting pump 520 which is connected to the gas exhausting pipe 510 and exhausts gases and air included in the reaction chamber 100. For example, the exhausting pump 520 may include a turbo pump or a rotary pump.

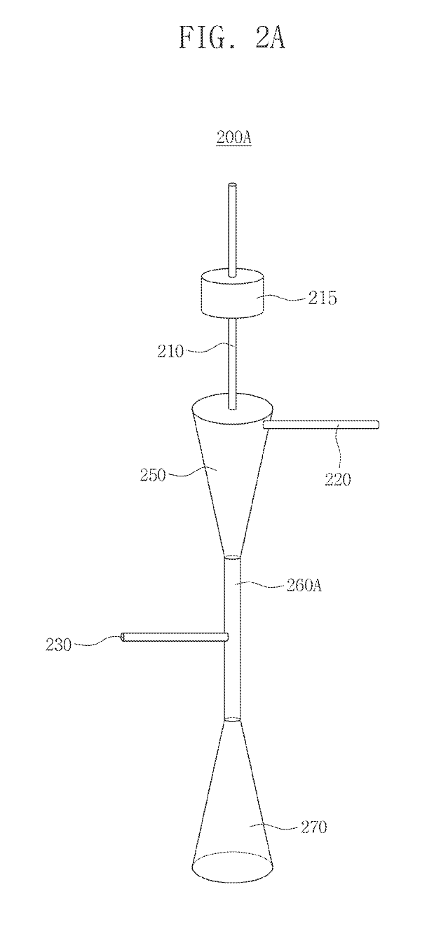

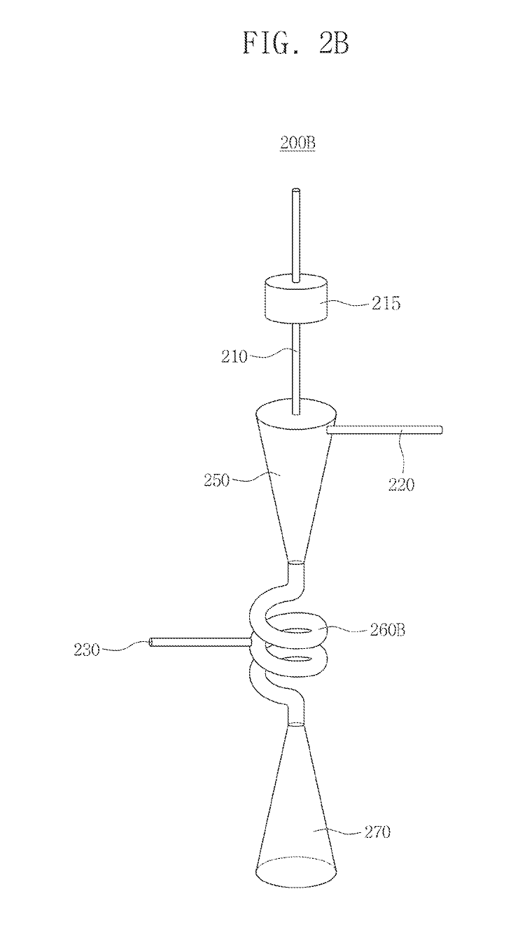

FIGS. 2A and 2B are schematic views illustrating gas supplies 200A and 200B according to various embodiments of the inventive concept.

Referring to FIG. 2A, a gas supply 200A in accordance with an embodiment of the inventive concept may include a first gas supply pipe 210, a second gas supply pipe 220, a third gas supply pipe 230, an upper gas mixer 250, an intermediate gas mixer 260A, and a lower gas mixer 270.

The first gas supply pipe 210 may be vertically positioned at a center of an upper portion of the upper gas mixer 250. For example, the first gas supply pipe 210 may vertically supply a first gas from the upper portion of the upper gas mixer 250 to an inside thereof. The first gas supply pipe 210 may have a circular shape having a smaller diameter than a minimum diameter of the upper gas mixer 250. For example, the first gas supply pipe 210 may have a diameter in a range of about 0.5 cm to 1.5 cm. The first gas supply pipe 210 may supply cleaning gases for cleaning the inside of the reaction chamber 100 and/or purge gases for purging source gases and reactive gases which remain in insides of the gas supply 200A, the shower head 400, and the reaction chamber 100, respectively. The cleaning gases may include halide gases such as an NF₃ gas, and the purge gases may include an inert gas such as N₂ gas or Ar gas.

The first gas supply pipe 210 may include a pushing part 215. The pushing part 215 may more strongly and forcibly inject the first gas into the upper gas mixer 250. The pushing part 215 may include a motor fan, a piston, or a rotary pump.

The second gas supply pipe 220 may be horizontally positioned at an upper portion of a side surface of the upper gas mixer 250. For example, the second gas supply pipe 220 may horizontally supply a second gas from the side surface of the upper gas mixer 250 to an inside thereof. The second gas supply pipe 220 may have a circular shape having a smaller diameter than the minimum diameter of the upper gas mixer 250. For example, the second gas supply pipe 220 may have a diameter in a range of about 0.5 cm to 1.5 cm and a length in a range of about 1.5 cm to 3 cm. The second gas supply pipe 220 may supply reactive gases, and/or purge gases for purging the source gases and/or the reactive gases which remain in the insides of the gas supply 200, the shower head 400, and the reaction chamber 100, respectively. The reactive gases may include nitriding agents or oxidizing agents such as NH₃, N₂O, NO, O₂, H₂O, or O₃ gases. In some embodiment, the second gas supply pipe 220 may be connected to an uppermost portion of the side surface of the upper gas mixer 250. For example, an upper surface of the upper gas mixer 250 and an upper surface of the second gas supply pipe 220 may be horizontally coplanar. Therefore, the second gas injected from the second gas supply pipe 220 into the upper gas mixer 250 may not flow backward or remain in the upper gas mixer 250.

The third gas supply pipe 230 may be horizontally disposed on a side surface of the intermediate gas mixer 260A. For example, the third gas supply pipe 230 may supply a third gas to an inside of the intermediate gas mixer 260A. The third gas supply pipe 230 may have a circular shape having a smaller diameter than a minimum diameter of the upper gas mixer 250, and/or the intermediate gas mixer 260A. For example, the third gas supply pipe 230 may have a diameter in a range of about 0.5 cm to 1.5 cm. The third gas supply pipe 230 may supply source gases, and/or purge gases for purging the source gases and/or the reactive gases which remain in the insides of the gas supply 200A, the shower head 400, and the reaction chamber 100. The source gases may include silicon source gas containing silicon such as silane (SiH₄) or dichlorosilane (SiH₄Cl₂).

The upper gas mixer 250 may have an inverted cone shape. For example, the upper gas mixer 250 may include an upper portion of which a diameter or an area is large and a lower portion of which a diameter or an area is small. In the upper gas mixer 250, the first gas supplied from the first gas supply pipe 210 and the second gas supplied from the second gas supply pipe 220 may be naturally mixed, and thus a first mixed gas may be generated. The first mixed gas including the first gas and the second gas, which are mixed in the upper gas mixer 250, may be supplied to the intermediate gas mixer 260A. The upper portion of the upper gas mixer 250 may have a planar surface. In the embodiment, for example, a maximum diameter of the upper portion of the upper gas mixer 250 may be in a range of about 2 cm to 4 cm, and a minimum diameter of the lower portion thereof may be in a range of about 0.5 cm to 1.5 cm.

The intermediate gas mixer 260A may be positioned under the upper gas mixer 250 to be connected to the lower portion of the upper gas mixer 250. The intermediate gas mixer 260A may have a thin circular shape. For example, the intermediate gas mixer 260A may include a venturi tube. A diameter of the intermediate gas mixer 260A may be the same as the minimum diameter of the upper gas mixer 250. The diameter of the intermediate gas mixer 260A may be in a range of about 0.5 cm to 2 cm. Since the diameter of the intermediate gas mixer 260A is less than an average diameter of the upper gas mixer 250, a flow velocity of the first mixed gas may be accelerated in the inside of the intermediate gas mixer 260A. For example, by the Bernoulli's theorem, the third gas is suctioned from the third gas supply pipe 230 and then a preliminary second mixed gas mixed with the first mixed gas may be generated. The preliminary second mixed gas in which all the first to third gases are mixed may be generated in the inside of the intermediate gas mixer 260A.

The lower gas mixer 270 may be positioned beneath the intermediate gas mixer 260A to be connected with a lower portion of the intermediate gas mixer 260A. The lower gas mixer 270 may have a cone shape. The lower gas mixer 270 may have an upper portion of which a diameter or an area is small and a lower portion of which a diameter or an area is large. For example, a minimum diameter of an upper portion of the lower gas mixer 270 may be in a range of about 0.5 cm to 1.5 cm, and a maximum diameter of a lower portion thereof may be in a range of about 2 cm to 4 cm. Since an average diameter of the lower gas mixer 270 is greater than the diameter of the intermediate gas mixer 260A, a flow velocity of the second mixed gas is decelerated. Therefore, a final second mixed gas in which the preliminary second mixed gas supplied from the intermediate gas mixer 260A is more uniformly mixed may be generated in the lower gas mixer 270.

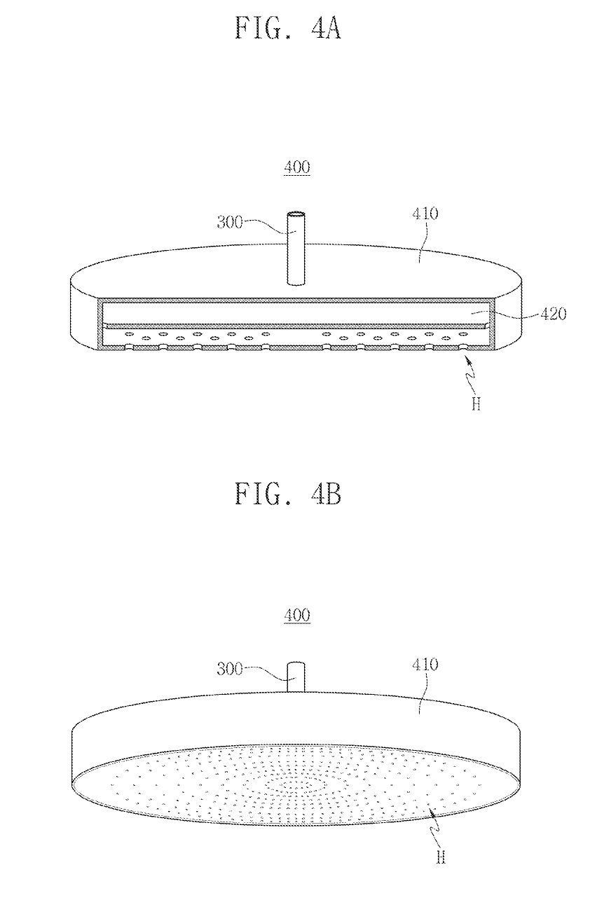

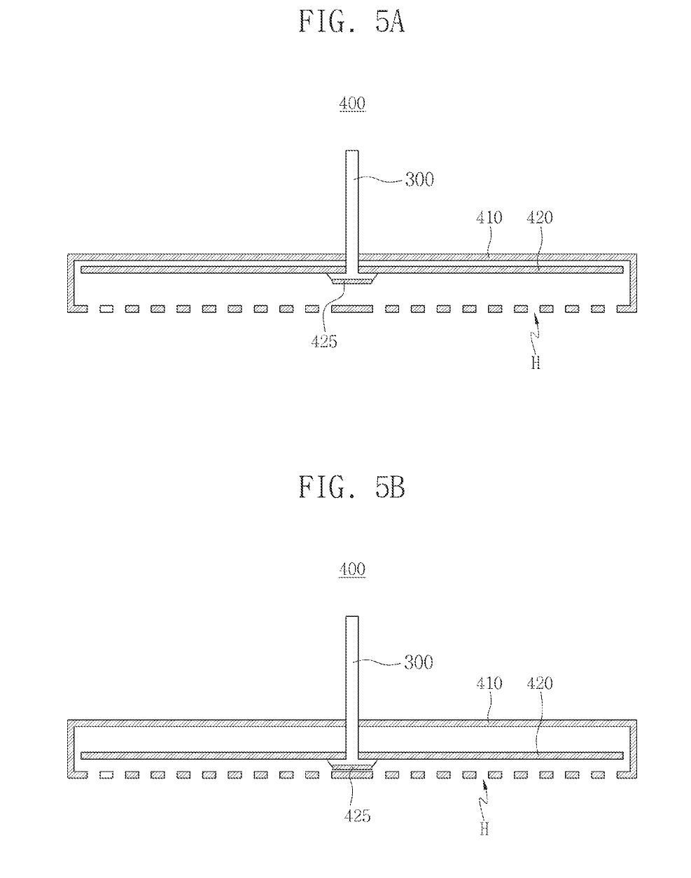

The gas mixed in the gas supply 200A may be supplied to the shower head 400. The gas supply 200A may be coupled to the shower head 400 by an interfacial joint 300 (shown in FIGS. 4A to 5B). The shower head 400 will be described in detail below.

Referring to FIG. 2B, a gas supply 200B in accordance with an embodiment of the inventive concept may include an intermediate gas mixer 260B having a spiral shape. Therefore, in the longer spiral-shaped intermediate gas mixer 260B, the first to third gases can be more uniformly mixed by a spiral-shaped vortex than the preliminary second mixed gas.

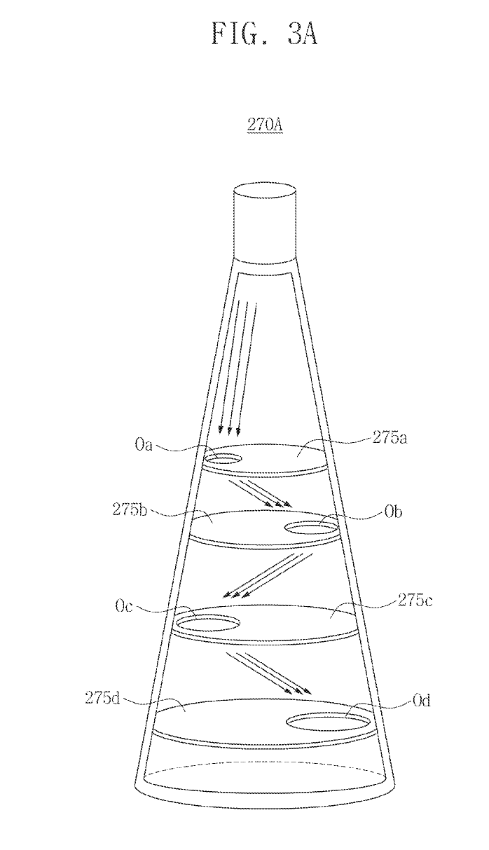

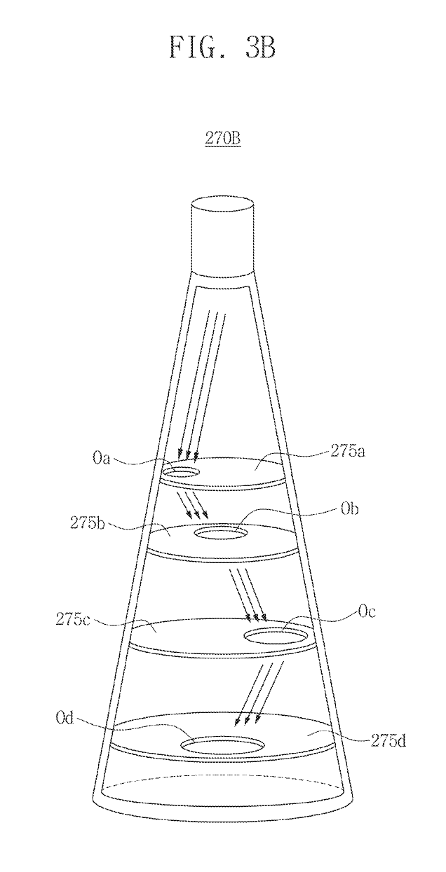

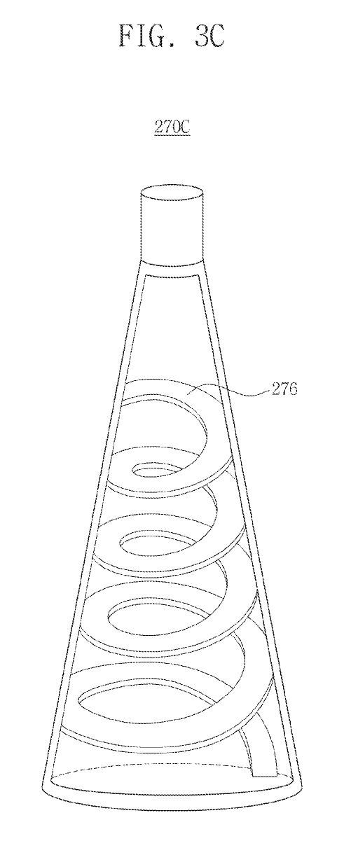

FIGS. 3A to 3C are schematic views illustrating an inside of a lower gas mixer 270 according to embodiments of the inventive concept.

Referring to FIGS. 3A and 3B, lower gas mixers 270A and 270B according to embodiments of the inventive concept may each include a plurality of partition plates 275a to 275d thereinside. The partition plates 275a to 275d may spatially separate insides of the lower gas mixers 270A and 270B. Each of the partition plates 275a to 275d may have one or more openings Oa to Od. The openings Oa to Od may spatially connect separated spaces. The centers of the openings Oa to Od may not be vertically aligned. For example, the openings Oa to Od may be arranged in a zigzag shape, a twist shape, or a rotating roulette shape when viewed in a top view. Therefore, since the mixed gas supplied from the intermediate gas mixer 260A has a vortex flow having a zigzag shape, a twist shape, or a cyclone shape while passing through the openings Oa to Od of the partition plates 275a to 275d in the insides of the lower gas mixers 270A and 270B, the final second mixed gas can be more uniformly mixed.

Referring to FIG. 3C, an inside of a lower gas mixer 270C according to an embodiment of the inventive concept may include a fin blade 276 having a spiral shape. The fin blade 276 may make the second mixed gas flow in a spiral shape in the inside of the lower gas mixer 270C.

FIGS. 4A and 4B are schematic views illustrating the shower head 400 in accordance with an embodiment of the inventive concept. Specifically, FIG. 4A is a cut-away perspective view of an upper portion of the shower head 400 and FIG. 4B is a cut-away perspective view of a lower portion of the shower head 400.

Referring to FIGS. 4A and 4B, the shower head 400 in accordance with the embodiment of the inventive concept may include a housing 410 having a hollow disc shape, and a spacing disc 420 having a disc shape. The interfacial joint 300 for being coupled to the lower gas mixer 270 may be disposed at the center of an upper portion of the housing 410. A lower surface of the housing 410 may have a plurality of gas distribution holes H.

The mixed gas supplied from the gas supply 200 may be supplied to the inside of the reaction chamber 100 through the spacing disc 420 and the gas distribution holes H disposed in the housing 410.

FIGS. 5A and 5B are schematic views illustrating an operation of the shower head 400.

Referring to FIGS. 5A and 5B, the spacing disc 420 may be moved upward and downward. Therefore, the mixed gas supplied from the gas supply 200 may be distributed and supplied in various ways in the inside of the housing 410 according to characteristics of processes. For example, when the mixed gas is sufficiently distributed toward an outside of the lower surface of the housing 410, a space in the housing 410 is increased by lifting the spacing disc 420, and the mixed gas may be sufficiently distributed toward the outside of the housing 410. On the other hand, when the spacing disc 420 is falling, the mixed gas is partially distributed toward the outside of the housing 410, and thus the mixed gas may be supplied to the inside of the reaction chamber 100 through the gas distribution holes H near the center of the housing 410.

A gas blocker 425 may be disposed at a center of the lower surface of the housing 410. The gas blocker 425 may distribute a flow of the mixed gas passed through the spacing disc 420 to the gas distribution holes H of the lower surface of the housing 410 in a radial form.

The apparatus for manufacturing semiconductor devices according to the embodiments of the inventive concept can manufacture the semiconductor devices using uniformly mixed gases, and thus patterns of the semiconductor devices can be uniformly formed.

The apparatus for manufacturing semiconductor devices according to the embodiments of the inventive concept can strongly and forcibly inject a first gas into a gas mixer, and thus the first gas and a second gas can be mixed well without a back flow of the second gas.

The apparatus for manufacturing semiconductor devices according to the embodiments of the inventive concept includes a gas mixer having a venturi tube shape, and thus gases can be more uniformly mixed.

The apparatus for manufacturing semiconductor devices according to the embodiments of the inventive concept can slow down a gas flow velocity and adjust a shape of a gas flow, and thus gases can be more uniformly mixed.

Although a few embodiments have been described with reference to the accompanying drawings, those skilled in the art will readily appreciate that many modifications are possible in embodiments without departing from the scope of the inventive concept and without changing essential features. Therefore, the above-described embodiments should be understood in a descriptive sense only and not for purposes of limitation.

What is claimed is:

1. An apparatus for manufacturing a semiconductor device, comprising:
a gas supply; and
a reaction chamber,
wherein the gas supply comprises:
an upper gas mixer;
an intermediate gas mixer positioned under the upper gas mixer;
a lower gas mixer positioned under the intermediate gas mixer;
a first gas supply pipe positioned on an upper portion of the upper gas mixer and configured to supply a first gas to the upper gas mixer;
a second gas supply pipe positioned on an upper end portion of a side surface of the upper gas mixer and configured to supply a second gas to the upper gas mixer; and
a third gas supply pipe positioned on a side surface of the intermediate gas mixer and configured to supply a third gas to the intermediate gas mixer.

2. The apparatus according to claim 1, wherein the upper gas mixer has an inverted cone shape of which an upper diameter is in a range of 2 cm to 4 cm and a lower diameter is in a range of 0.5 cm to 1.5 cm.

3. The apparatus according to claim 1, wherein the intermediate gas mixer has a circular shape of which a diameter is in a range of 0.5 cm to 2 cm to be less than those of the upper gas mixer and the lower gas mixer.

4. The apparatus according to claim 3, wherein the intermediate gas mixer has a spiral shape.

5. The apparatus according to claim 1, wherein the lower gas mixer has a cone shape of which an upper diameter is in a range of 0.5 cm to 1.5 cm and a lower diameter is in a range of 2 cm to 4 cm.

6. The apparatus according to claim 5, wherein:
the lower gas mixer comprises partition plates configured to separate an inside of the lower gas mixer into a plurality of spaces; and
each of the partition plates includes at least one opening.

7. The apparatus according to claim 6, wherein the lower gas mixer comprises a fin blade having a spiral shape.

8. The apparatus according to claim 1, wherein the first gas supply pipe comprises one of a motor fan, a piston, and a rotary pump.

9. The apparatus according to claim 1, wherein:
the first gas comprises a cleaning gas;
the second gas comprises a nitriding agent gas or an oxidizing agent gas; and
the third gas comprises a silicon source gas.

10. The apparatus according to claim 1, further comprising a shower head connected to the gas supply and positioned on an upper portion of the reaction chamber,
wherein the shower head comprises:
a housing having a plurality of gas distribution holes in a lower portion thereof; and
a spacing plate configured to be movable upward and downward.

11. An apparatus for manufacturing semiconductor devices, comprising:
a gas supply;
a shower head; and
a reaction chamber,
wherein the gas supply comprises:
an upper gas mixer;
an intermediate gas mixer connected to a lower portion of the upper gas mixer;
a lower gas mixer connected to a lower portion of the intermediate gas mixer and having a cone shape;
a first gas supply pipe connected to an upper portion of the upper gas mixer;
a second gas supply pipe connected to a side portion of the upper gas mixer; and
a third gas supply pipe connected to a side portion of the intermediate gas mixer,
wherein each of the first gas supply pipe, the second gas supply pipe and the third gas supply pipe has a circular shape having a smaller diameter than the intermediate gas mixer.

12. The apparatus according to claim 11, wherein the upper gas mixer has an inverted cone shape of which an upper diameter is in a range of 2 cm to 4 cm and a lower diameter is in a range of 0.5 cm to 1.5 cm to be greater than a diameter of the intermediate gas mixer.

13. The apparatus according to claim 11, wherein the intermediate gas mixer has a circular shape of which an average diameter is less than an average diameter of the upper gas mixer and an average diameter of the lower gas mixer.

14. The apparatus according to claim 11, wherein the first gas supply pipe comprises one of a motor fan, a piston, and a rotary pump.

15. The apparatus according to claim 11, wherein the lower gas mixer includes a partition plate or a fin blade for adjusting a gas flow thereinside.

16. An apparatus for manufacturing semiconductor devices, comprising:
a gas supply;
a shower head; and
a reaction chamber,
wherein the gas supply comprises:
an upper gas mixer having an inverted cone shape of which an upper portion is large and a lower portion is small;
an intermediate gas mixer connected to the lower portion of the upper gas mixer and having a circular shape;
a lower gas mixer connected to a lower portion of the intermediate gas mixer and having a cone shape of which an upper portion is small and a lower portion is large;
a first gas supply pipe configured to supply a first gas to the upper gas mixer and having a smaller diameter than an average diameter of the upper gas mixer;
a second gas supply pipe configured to supply a second gas to the upper gas mixer and having a smaller diameter than the average diameter of the upper gas mixer; and
a third gas supply pipe configured to supply a third gas to the intermediate gas mixer and having a smaller diameter than the average diameter of the upper gas mixer.

17. The apparatus according to claim 16, wherein the first gas supply pipe is disposed on an upper portion of the upper gas mixer and supplies a cleaning gas and a purge gas to the upper gas mixer.

18. The apparatus according to claim 16, wherein the second gas supply pipe is positioned on an upper end portion of a side surface of the upper gas mixer and supplies a nitriding agent gas or an oxidizing agent gas, and a purge gas to the upper gas mixer.

19. The apparatus according to claim 16, wherein the third gas supply pipe is positioned on a side portion of the intermediate gas mixer and supplies a silicon source gas and a purge gas to the intermediate gas mixer.

20. The apparatus according to claim 16, wherein the lower gas mixer comprises partition plates having openings arranged in a zigzag shape, a twist shape, or a roulette shape, or a fin blade having a spiral shape.
